(19) United States
(12) Patent Application Publication
(10) Pub. No.: US 2016/0064639 A1
(43) Pub. Date: Mar. 3, 2016

(54) PIEZOELECTRIC DRIVING APPARATUS AND PIEZOELECTRIC DRIVING METHOD

(71) Applicant: SAMSUNG ELECTRO-MECHANICS CO., LTD., Suwon-Si (KR)

(72) Inventors: Chan Woo PARK, Suwon-Si (KR); Peter LIM, Suwon-Si (KR); Joo Yul KO, Suwon-Si (KR); Ho Kwon YOON, Suwon-Si (KR)

(73) Assignee: SAMSUNG ELECTRO-MECHANICS CO., LTD., Suwon-Si (KR)

(21) Appl. No.: 14/727,933

(22) Filed: Jun. 2, 2015

(30) Foreign Application Priority Data
Aug. 29, 2014 (KR) 10-2014-0114284

(51) Int. Cl. H01L 41/04; H01L 41/083

(52) U.S. Cl. CPC H01L 41/042; H01L 41/083

(57) ABSTRACT

A piezoelectric driving apparatus according to an exemplary embodiment includes: a waveform synthesizer outputting a digital value; a digital-to-analog converter outputting an analog value corresponding to the digital value; and an output unit applying an offset voltage to the analog value to generate and output an asymmetrical driving signal.

### CROSS-REFERENCE TO RELATED APPLICATION

This application claims the priority and benefit under 35 USC 119(a) of Korean Patent Application No. 10-2014-0114284 filed on Aug. 29, 2014, with the Korean Intellectual Property Office, the entire disclosure of which is incorporated herein by reference for all purposes.

### BACKGROUND

1. Field

The following description relates to a piezoelectric driving apparatus and a piezoelectric driving method.

2. Description of Related Art

A multilayer piezoelectric element formed of a plurality of piezoelectric layers may be problematic, in that a magnitude of a driving voltage may be limited. That is, in a case in which a high level driving voltage, having a polarity opposite to that of the piezoelectric layer, is applied to the multilayer piezoelectric element, since the driving voltage affects polarization characteristics of a dielectric material of the multilayer piezoelectric element, the piezoelectric characteristics of the dielectric material may be lost.

Therefore, the multilayer piezoelectric element formed of a plurality of piezoelectric layers has very limited operating voltage. In addition, due to such limitations on the operating voltage, output characteristics of the piezoelectric element may be decreased.

### SUMMARY

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a piezoelectric driving apparatus includes a waveform generator configured to output an alternating current (AC) signal; an output unit configured to apply an offset voltage to the AC signal to generate and output an asymmetrical driving signal; and a correcting unit configured to correct the offset voltage in at least one section of the asymmetrical driving signal of a piezoelectric element.

The waveform generator may include a waveform synthesizer configured to output a digital value; and a digital-to-analog converter configured to output an analog value corresponding to the digital value.

The correcting unit may be configured to selectively prevent the offset voltage from being applied to the asymmetrical driving signal in a standby state section of the asymmetrical driving signal.

The output unit may be configured to generate a pair of differential signals using the analog value and apply the pair of differential signals to both terminals of the piezoelectric element, respectively.

The output unit may be configured to apply a positive offset voltage to one of the differential signals input to a positive input terminal of the piezoelectric element and apply a negative offset voltage to the other of the differential signals input to a negative input terminal of the piezoelectric element.

The correcting unit may be further configured to apply the negative offset voltage to the differential signal input to the positive input terminal and apply the positive offset voltage to the differential signal input to the negative input terminal in the standby state section of the asymmetrical driving signal.

The output unit may include: a differential signal generator configured to generate a pair of differential signals using the analog value; and first and second amplifiers configured to apply the offset voltage to the pair of differential signals, respectively.

The correcting unit may be configured to subtract the offset voltage from output values of the first and second amplifiers in a standby state section of the asymmetrical driving signal.

The correcting unit may be configured to control the first and second amplifiers to block the offset voltage in a standby state section of the asymmetrical driving signal.

The output unit may further include a voltage distributor connected to reference terminals of the first and second amplifiers and provide the offset voltage to each of the first and second amplifiers.

The correcting unit may be configured to sequentially output a plurality of digital values by repeatedly subtracting a predetermined value from a final digital value of the driving signal when the generating of the driving signal ends.

In another general aspect, a piezoelectric driving apparatus includes: a waveform synthesizer configured to output a digital value; a digital-to-analog converter configured to output an analog value corresponding to the digital value; an output unit configured to generate an output waveform using the analog value and shift the same to output a shifted waveform; and a correcting unit configured to control the output unit to block a shift operation in at least one section of the output waveform.

The output unit may include: a differential signal generator configured to generate a pair of differential signals using the analog value; and first and second amplifiers configured to apply an offset voltage to the pair of differential signals, respectively.

The first amplifier may be configured to apply a positive offset voltage to a first differential signal of the pair of differential signals to shift a waveform of the first differential signal in a positive voltage direction, and the second amplifier may apply a negative offset voltage to a second differential signal of the pair of differential signals to shift a waveform of the second differential signal in a negative voltage direction.

The correcting unit may be configured to control the first and second amplifiers to selectively block the shift operation in a standby state section of the output waveform.

The correcting unit may be configured to correct the output waveform to have a predetermined gradient when the generating of the output waveform ends.

According to another general aspect, a piezoelectric driving apparatus for driving a piezoelectric element in which a plurality of piezoelectric layers are stacked, the piezoelectric driving apparatus includes: an output unit configured to provide a first differential signal to which a positive offset voltage has been applied to a positive input terminal of the piezoelectric element, and provide a second differential signal to which a negative offset voltage has been applied to a negative input terminal of the piezoelectric element; and a correcting unit configured to control the output unit to block the positive offset voltage and/or the negative offset voltage in at least one section of the first and second differential signals.

The piezoelectric driving apparatus may further include: a waveform synthesizer configured to output a digital value; a digital-to-analog converter configured to output an analog value corresponding to the digital value; and an output unit configured to apply an offset voltage to the analog value to generate an asymmetrical driving signal.

The output unit may be configured to apply the positive offset voltage to the first differential signal, and apply the negative offset voltage to the second differential signal.

The correcting unit may be further configured to apply the negative offset voltage to the first differential signal, and apply the positive offset voltage to the second differential signal in a standby state section of the asymmetrical driving signal.

In yet another general aspect, a piezoelectric driving method includes: selecting a digital value; generating first and second analog signals using the digital value; applying offset voltages having opposite polarities and magnitudes to the first and second analog signals to generate an asymmetrical driving signal when the first and second analog signals are not in a standby state section; and, driving a multi-layer piezoelectric element according to the asymmetrical driving signal.

The first and second analog signals may be output in the standby state section.

In another general aspect, a non-transitory computer-readable medium stores instructions for causing a controller to perform the method described above.

In another general aspect, a multi-layer piezoelectric actuator includes: a plurality of piezoelectric layers arranged in stacked relation, each piezoelectric layer having a predetermined thickness; a plurality of alternatingly arranged first and second electrodes disposed within the stacked piezoelectric layers; a piezoelectric driver coupled to the first and second electrodes, the piezoelectric driver configured to adaptively adjust an asymmetric driving signal according to at least the predetermined thickness and/or number of piezoelectric layers, the asymmetric driving signal having an absolute value of a magnitude of a positive polarity greater than an absolute value of a magnitude of a negative polarity.

The plurality of piezoelectric layers may include about 8 to about 24 layers and each layer may be about 15 μm to about 100 μm thick.

Other features and aspects will be apparent from the following detailed description, the drawings, and the claims.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a configuration diagram of an electronic device according to an exemplary embodiment in the present disclosure;

FIG. 2 is a cross-sectional view of a multilayer piezoelectric element according to an exemplary embodiment in the present disclosure;

FIG. 3 is a graph illustrating an example of a pair of differential signals which may be applied to both terminals of the multilayer piezoelectric element;

FIG. 4 is a graph illustrating the exemplary differential signals of FIG. 3 as one driving signal;

FIG. 5 is a graph illustrating voltage characteristics for an example of a multilayer piezoelectric element having twelve piezoelectric layers;

FIG. 6 is a configuration diagram illustrating an example of a piezoelectric driving apparatus according to an exemplary embodiment in the present disclosure;

FIG. 7 is a configuration diagram illustrating another example of the piezoelectric driving apparatus according to an exemplary embodiment in the present disclosure;

FIG. 8 illustrates signals output from respective components of the piezoelectric driving apparatus according to an exemplary embodiment in the present disclosure;

FIG. 9 illustrates an example of differential signals output from an output unit;

FIG. 10 illustrates an example of differential signals corrected by a correcting unit;

FIG. 11 is a graph illustrating the differential signals of FIG. 10 as one driving signal;

FIG. 12 is a configuration diagram illustrating an example of an output unit of the piezoelectric driving apparatus;

FIG. 13 is a circuit diagram illustrating an example of an amplifier of FIG. 12;

FIG. 14 is a configuration diagram illustrating an example of a correcting unit which may be applied to the example of FIG. 12;

FIG. 15 is a configuration diagram illustrating another example of the output unit of the piezoelectric driving apparatus;

FIG. 16 is a configuration diagram illustrating an example of a correcting unit which may be applied to the example of FIG. 15;

FIG. 17 is a graph illustrating an exemplary operation of the correction unit; and

FIG. 18 is a flowchart illustrating an example of a piezoelectric driving method. Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

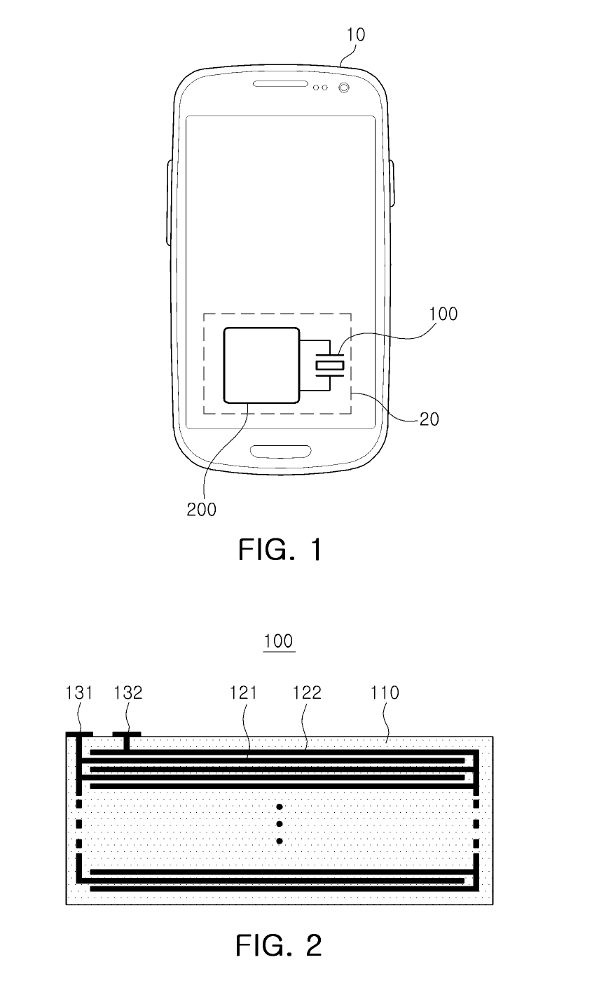

FIG. 1 is a configuration diagram of an exemplary electronic device according to an exemplary embodiment in the present disclosure.

As illustrated in FIG. 1, an electronic device 10 includes a piezoelectric actuator 20. The piezoelectric actuator 20 may provide vibration or user reactivity to the electronic device 10. For example, the piezoelectric actuator 20 may provide vibration in response to a touch of a user.

The piezoelectric actuator 20 includes a multilayer piezoelectric element 100 and a piezoelectric driving apparatus 200. The multilayer piezoelectric element 100 includes a plurality of stacked piezoelectric layers.

The piezoelectric driving apparatus 200 may generate an asymmetrical driving signal using an offset voltage and apply the asymmetrical driving signal to the piezoelectric element 100.

According to an exemplary embodiment, the piezoelectric driving apparatus 200 may provide a first differential signal to which a positive offset voltage is applied to a positive input terminal of the piezoelectric element and provide a second differential signal to which a negative offset voltage is applied to a negative input terminal of the piezoelectric element, but may not apply the positive offset voltage or the negative offset voltage to at least some sections of first and second driving signals.

The multilayer piezoelectric element 100 and the piezoelectric driving apparatus 200 as described above will be described below in more detail.

Although FIG. 1 illustrates a smartphone as an example of the electronic device, it is merely an example, and the electronic device may collectively refer to independently drivable computing apparatuses such as tablets, PCs, smartwatches, head-mounted displays, navigation systems for vehicles, and the like.

FIG. 2 is a cross-sectional view of a multilayer piezoelectric element according to an exemplary embodiment in the present disclosure.

As illustrated in FIG. 2, the multilayer piezoelectric element 100 according to the present exemplary embodiment may be configured as a multilayer body in which a plurality of piezoelectric layers 110 are stacked, wherein internal electrodes 121 and 122 are alternatingly formed in the plurality of piezoelectric layers 110. The internal electrodes 121 and 122 include positive electrode internal electrodes 121 and negative electrode internal electrodes 122.

The positive electrode internal electrodes 121 and the negative electrode internal electrodes 122 are alternatingly disposed on the plurality of piezoelectric layers 110 so as to be stacked together with the plurality of piezoelectric layers 110, thereby forming the multilayer piezoelectric element 100.

The plurality of piezoelectric layers 110 may be formed of a ceramic material and may be manufactured in a planar ceramic sheet form using particulate ceramic powders. A plurality of ceramic sheets may be stacked to configure each of the piezoelectric layers 110 and the piezoelectric layers 110 may configure the multilayer body to generate displacement in a length direction or an end surface direction of the multilayer body by applying a voltage to the multilayer body. Here, the voltage applied to the multilayer body in which the piezoelectric layers 110 are stacked may be applied through the internal electrodes 121 and 122 formed on the piezoelectric layers 110.

The internal electrodes 121 and 122 may be formed of a metal material having excellent conductivity and may be mainly formed of a metal material of an alloy of Ag (Silver) and Pd (Palladium). The internal electrodes 121 and 122 form a positive electrode and a negative electrode in the multilayer body in which the plurality of piezoelectric layers 110 are stacked and may be alternatingly and repeatedly stacked on the piezoelectric layers 110, thereby configuring the multilayer piezoelectric element having polarity.

In addition, the internal electrodes 121 and 122 disposed between the piezoelectric layers 110 and having the same polarity may be electrically connected to each other while alternatingly forming the positive electrode and the negative electrodes, and the internal electrodes 121 and 122 having the respective polarities may be electrically connected respectively to a positive electrode terminal 131 and a negative electrode terminal 132 exposed to one surface of the multilayer body through lead wires.

Therefore, the multilayer piezoelectric element 100 may be applied with driving signals from the piezoelectric driving apparatus 200 through the positive electrode terminal 131 and the negative electrode terminal 132.

Since the multilayer piezoelectric element 100 has a magnitude of a driving voltage which is relatively smaller than that of a single multilayer piezoelectric element, it may generate the same output while consuming less power. Therefore, it has been popularized to use the multilayer piezoelectric element 100 in a field in which power management is important.

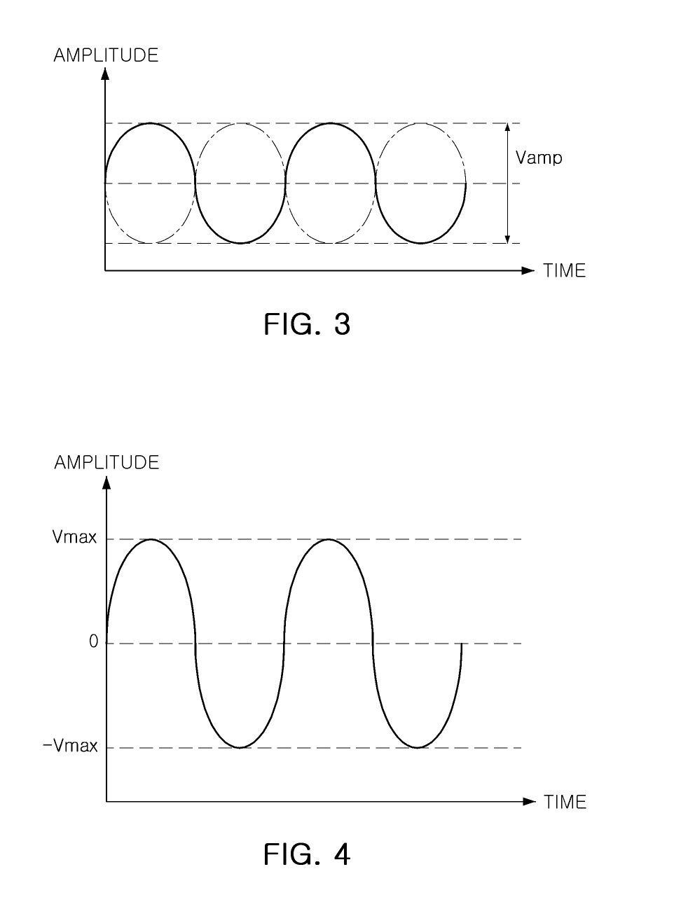

FIG. 3 is a graph illustrating an example of a pair of differential signals which may be applied to both terminals 131, 132 of the multilayer piezoelectric element and FIG. 4 is a graph illustrating the differential signals of FIG. 3 as one driving signal.

The graph of FIG. 3 illustrates an example of a pair of differential signals having a phase difference of 180 degrees or less. The pair of differential signals may be respectively input to both terminals of the multilayer piezoelectric element. For example, the signal denoted by the bold solid line may be input to a positive electrode terminal of the multilayer piezoelectric element and the signal denoted by the alternating long and short dashed line may be input to a negative electrode terminal of the multilayer piezoelectric element.

In the illustrated example, differential signals having amplitudes which are symmetrical with each other are illustrated. That is, the differential signals in the illustrated example have positive amplitude (Vamp1) and negative amplitude (Vamp2) having the same magnitude as each other.

FIG. 4 is a graph illustrating the differential signals of FIG. 3 as one driving signal. The graph of FIG. 4 may be derived by subtracting a second signal applied to a negative input terminal of the piezoelectric element of FIG. 2 from a first signal applied to a positive input terminal of the piezoelectric element of FIG. 2.

The differential signals of FIG. 3 may be signals which are physically applied to both terminals of the multilayer piezoelectric element respectively and the signal of FIG. 4 may be a driving signal which is logically applied to the multilayer piezoelectric element. As described above, it may be appreciated that the driving signal applied to the multilayer piezoelectric element illustrated in FIG. 4 also has a symmetrical form.

As described above with reference to FIGS. 3 and 4, a symmetrical driving signal may be used as an example of driving the multilayer piezoelectric element. However, in the case of using the symmetrical driving signal, magnitude of the applied driving signal, that is, a voltage value should be limited.

The reason is that characteristics of the multilayer piezoelectric element may be lost in the case in which a level of voltage applied in an inverse direction of polarization characteristics of the multilayer piezoelectric element is large. In addition, as the stacked number of multilayer piezoelectric elements is increased, a limitation for a voltage which may be applied to the multilayer piezoelectric element may also be increased.

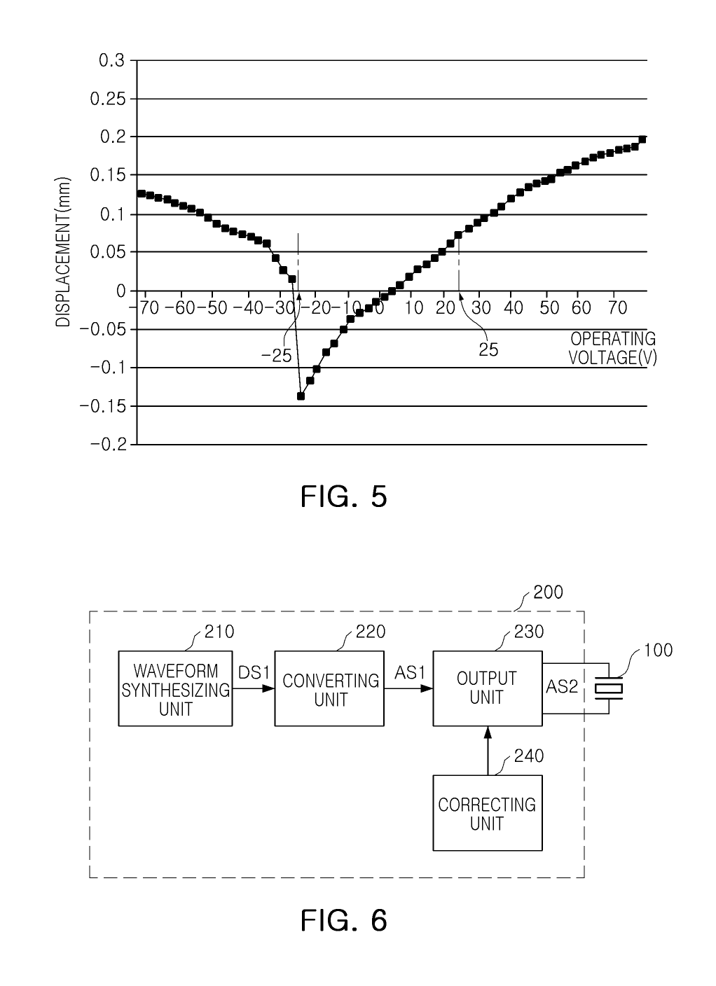

FIG. 5 is a graph illustrating an example of displacement depending on a voltage applied to the multilayer piezoelectric element and a voltage limitation for the multilayer piezoelectric element will be described with reference to FIG. 5.

The example illustrated in FIG. 5 is a graph illustrating voltage characteristics for an example of a multilayer piezoelectric element having twelve piezoelectric layers.

As illustrated in the graph, it may be appreciated that an operation displacement of the multilayer piezoelectric element is increased in a positive region of the driving voltage as the magnitude of the applied voltage is increased. For example, as the applied operation voltage is increased from 0V to 70V, it may be appreciated that the displacement of the multilayer piezoelectric element is increased. The reason is that the voltage is applied in a forward direction of polarization characteristics of the multilayer piezoelectric element.

On the other hand, it may be appreciated that a reverse displacement occurs at a predetermined voltage or less in a negative region of the driving voltage. That is, it may be appreciated that a negative operation displacement of the multilayer piezoelectric element is increased as an absolute value of the applied voltage is increased, up to a predetermined threshold value of a negative operating voltage, but a negative displacement is rapidly changed to a positive displacement in the case in which a negative voltage exceeding the predetermined threshold value is applied.

This phenomenon may occur since the voltage having reverse polarity opposite to polarization characteristics of the multilayer piezoelectric element is strongly applied to the multilayer piezoelectric element to depolarize the multilayer piezoelectric element, and in the case in which this phenomenon occurs, characteristics of the multilayer piezoelectric element may be lost.

As a result, in the case in which the driving voltage in a negative direction is strongly applied to the multilayer piezoelectric element, polarization characteristics of the piezoelectric layer of the multilayer piezoelectric element may be lost and consequently, operational characteristics of the multilayer piezoelectric element may be lost.

Here, the threshold value causing the depolarization may be changed depending on a thickness, a material, or the like of the multilayer piezoelectric element. In the example illustrated in FIG. 5, it may be appreciated that the threshold value is about −25V.

Consequently, in the case of the example illustrated in FIG. 5, as the driving voltage of the multilayer piezoelectric element, the driving voltage having a voltage range larger than the negative threshold value, that is, −25V is employed. Therefore, in the case in which the symmetrical driving signal as described above is used, the driving voltage is limited to a range of −25V to +25V. That is, in the case in which the symmetrical driving signal is used, there is a positive voltage threshold value corresponding to a negative voltage threshold value of the multilayer piezoelectric element.

In addition, since the negative threshold value of the driving voltage causing the depolarization is increased as the number of multilayer piezoelectric elements is increased or a thickness of each stack decreases, an available range of the driving voltage may become smaller.

Hereinafter, as an exemplary embodiment in the present disclosure, a piezoelectric driving technology using an asymmetrical driving signal will be described.

The piezoelectric driving technology to be described below may provide a higher output while satisfying the negative threshold value of the multilayer piezoelectric element as described above, by applying an asymmetrical driving signal to the multilayer piezoelectric element.

For example, as in the example illustrated in FIG. 5, when the negative voltage threshold value at which characteristics of the multilayer piezoelectric element are lost is −25V, a negative value of the driving signal and a positive value of the driving signal may be used to be asymmetrical with each other by setting a range of the driving signal to be larger than −25 and smaller than 35V.

In the asymmetrical driving signal, an absolute value of a positive peak value may be larger than an absolute value of a negative peak value. In this case, since a range of the positive operating voltage may be increased more while satisfying the negative voltage threshold value so that piezoelectric characteristics are not lost, the multilayer piezoelectric element may generate the higher output. That is, since the case of using the asymmetrical driving signal has a peak-to-peak voltage which is larger than that of a case of using the symmetrical driving signal, the higher output may be generated while satisfying the negative voltage threshold value of the piezoelectric element.

According to an exemplary embodiment, the multilayer piezoelectric element may be formed by stacking about eight to about twenty four piezoelectric layers, each of which has a thickness of about 15 μm (micrometers) or more to about 100 μm or less.

The following Table 1 illustrates the number of piezoelectric layers of the multilayer piezoelectric element and amplitudes of driving signals depending on the number of piezoelectric layers. In Table 1, the thickness of the piezoelectric layer may be about 10 μm to about 100 μm.

TABLE 1

| Number of Piezoelectric | Negative Minimum | Positive Maximum |
|---|---|---|
| Layers | Amplitude | Amplitude |
| 12 | −25 | 35 |
| 24 | −12.5 | 17.5 |

In an example illustrated in Table 1, the multilayer piezoelectric element is formed by stacking twelve piezoelectric layers and the amplitude of the driving signal which is input to the multilayer piezoelectric element may have values of about −25V at minimum to about 35V at maximum. In another example, the multilayer piezoelectric element is formed by stacking twenty four piezoelectric layers and the amplitude of the driving signal which is input to the multilayer piezoelectric element may have values of about −12V at minimum to about 18V at maximum.

Referring to Table 1, it may be appreciated that the range of the driving signal which is applied to the multilayer piezoelectric element is changed depending on the number of piezoelectric layers. Generally, it may be appreciated that the negative threshold value of the driving signal (i.e., the negative threshold value at which characteristics of the multilayer piezoelectric element are lost) is increased (or becomes less negative) as the number of piezoelectric layers is increased or the thickness of the piezoelectric layer is reduced.

As described above, it may be appreciated that the driving signal is applied by setting a negative voltage range and a positive voltage range to be asymmetrical with each other in an exemplary embodiment in the present disclosure. Hereinafter, various exemplary embodiments of a piezoelectric driving apparatus and circuit using the asymmetrical signal will be described in more detail with reference to FIGS. 6 through 13.

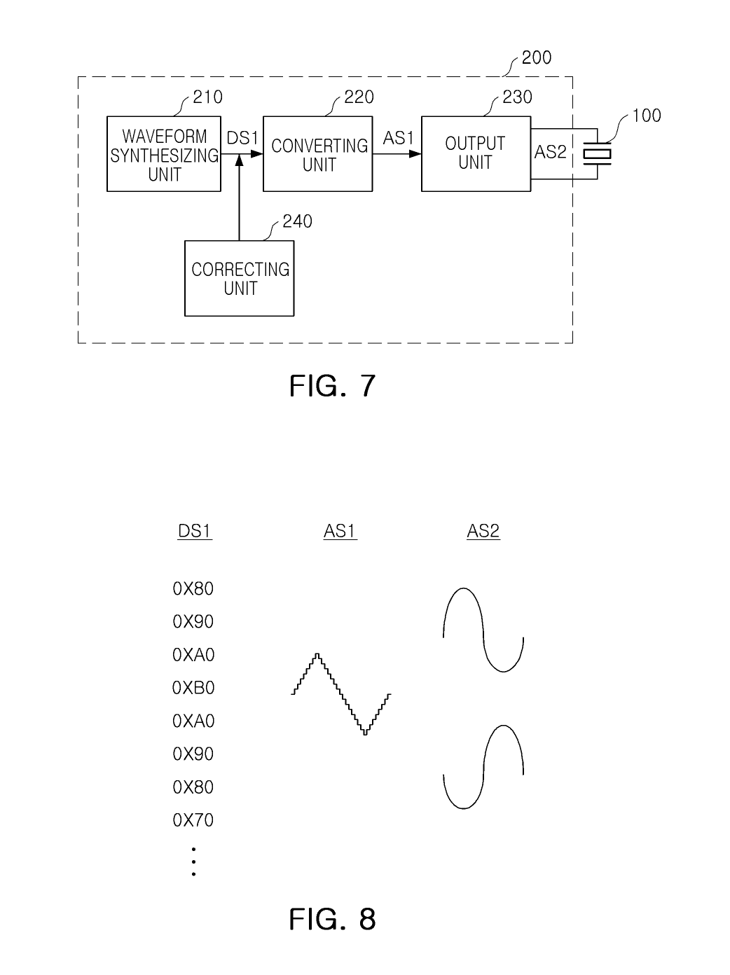

FIG. 6 is a configuration diagram illustrating an example of a piezoelectric driving apparatus according to an exemplary embodiment in the present disclosure and FIG. 7 is a configuration diagram illustrating another example of the piezoelectric driving apparatus according to an exemplary embodiment in the present disclosure.

The piezoelectric driving apparatus 200 may apply a predetermined driving signal to the multilayer piezoelectric element 100, so as to drive the multilayer piezoelectric element 100. By way of example, the piezoelectric driving apparatus 200 may provide a pair of differential signals to both terminals of the multilayer piezoelectric element 100 respectively, so as to drive the multilayer piezoelectric element 100. The differential signals may be complementary (equal and opposite) or opposite and asymmetric.

Hereinafter, a pair of signals which are physically applied to both terminals of the multilayer piezoelectric element 100 respectively is referred to as differential signals, and a signal which is applied to the multilayer piezoelectric element 100 by the pair of differential signals is referred to as a driving signal.

The exemplary piezoelectric driving apparatus 200 includes waveform generating units 210 and 220, an output unit 230, and a correcting unit 240. The waveform generating units 210 and 220 may output an alternating current signal.

According to an exemplary embodiment in the present disclosure, the waveform generating units 210 and 220 may include a waveform synthesizing unit 210 outputting a digital value and a digital-to-analog converting unit 220 outputting an analog value corresponding to the digital value.

Alternatively, as another exemplary embodiment, the waveform generating unit may include a predetermined function outputting the digital value and a digital-to-analog converting unit outputting the digital value output from the function as an analog value.

Hereinafter, a description will be provided based on an exemplary embodiment in which the waveform generating unit includes the waveform synthesizing unit 210 and the digital-to-analog converting unit 220, but it will be apparent that various modified embodiments of the waveform generating unit are included in the scope of the present disclosure.

The output unit 230 may generate an asymmetrical driving signal using the alternating current signal output from the waveform generating units 210 and 220. For example, the output unit 230 may generate the asymmetrical driving signal by applying an offset voltage to the alternating current signal.

According to another exemplary embodiment, the offset voltage may also be applied by the waveform synthesizing unit 210.

The correcting unit 240 may correct the offset voltage for at least some sections of the asymmetrical driving signal.

According to an exemplary embodiment, the output unit 230 applies the offset voltage to the alternating current signal and the correcting unit 240 may correct an output of the output unit 230 so that the offset voltage is not applied to at least some sections of the asymmetrical driving signal. FIG. 6 illustrates an example as described above.

According to another exemplary embodiment, the waveform synthesizing unit 210 may generate the asymmetrical driving signal by applying the offset value to the output digital value and the correcting unit 240 may control the waveform synthesizing unit 210 so as not to apply the offset value to at least some sections of the asymmetrical driving signal. FIG. 7 illustrates an example as described above.

FIG. 8 illustrates signals output from respective components of the piezoelectric driving apparatus according to an exemplary embodiment in the present disclosure.

Referring to further FIG. 8, the waveform synthesizing unit 210 outputs a digital value DS1.

The converting unit 220 converts the input digital value DS1 into an analog value AS1 and outputs the converted analog value AS1. The converting unit 220 may convert the digital value DS1 into the analog value AS1 at a predetermined period and output an analog signal (a graph of illustrated step waveform).

The output unit 230 may output an input analog value. The output unit 230 may generate the asymmetrical driving signal using the input analog value.

The output unit 230 may include a differential amplifier, and generate two sine waves, that is, differential signals AS2 using the input analog signal AS1, so as to be respectively provided to both input terminals of the piezoelectric element 100. The output unit 230 may generate the asymmetrical driving signal by shifting the respective waveforms of the differential signals or only the negative signal may be shifted up.

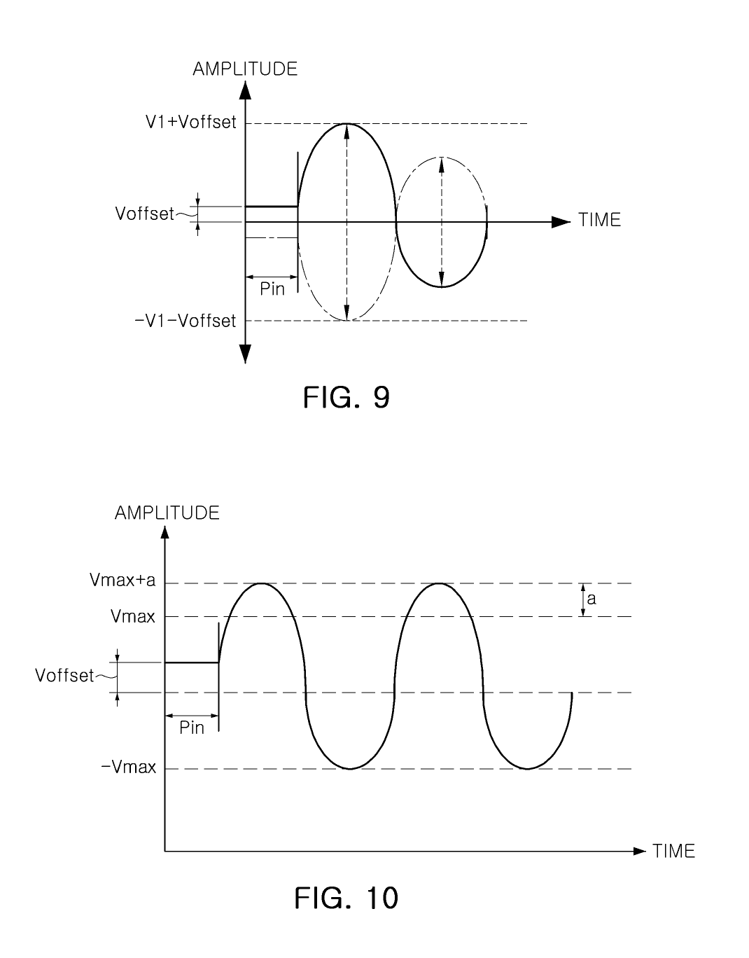

FIG. 9 illustrates an example of the differential signals output from the output unit 230.

Each of the differential signals may be each input to both terminals of the piezoelectric element 100. A pair of differential signals may have phases opposite to each other.

The pair of differential signals may be first and second signals having maximum amplitude of first polarity and maximum amplitude of second polarity which are different from each other. That is, the first differential signal denoted by a solid line may be applied to a positive input terminal of the piezoelectric element 100 and the second differential signal denoted by the alternating long and short dashed line may be applied to a negative input terminal of the piezoelectric element 100. Here, it may be appreciated that the first differential signal applied to the positive input terminal has positive maximum amplitude larger than that of the second differential signal and negative maximum amplitude smaller than that of the second differential signal.

The output unit 230 may shift respective waveforms of the differential signals.

According to an exemplary embodiment, the waveform of the first differential signal may be shifted in a positive direction, and the waveform of the second differential signal may be shifted in a negative direction. In this case, the first differential signal may be applied to the positive input terminal of the multilayer piezoelectric element 100 and the second differential signal may be applied to the negative input terminal of the multilayer piezoelectric element 100.

According to an exemplary embodiment in the present disclosure, the output unit 230 may shift the waveforms of the differential signals by applying the offset voltage thereto. For example, the output unit 230 may apply a positive offset voltage Voffset to the first differential signal input to the positive input terminal of the piezoelectric element 100 and apply a negative offset voltage Voffset to the second differential signal input to the negative input terminal of the piezoelectric element 100.

Depending on exemplary embodiments, the positive offset voltage and the negative offset voltage may also have values corresponding to each other, or may also have different absolute values.

As illustrated in FIG. 9, the pair of differential signals output from the output unit 230 may be shifted so as to become the asymmetrical driving signal.

In the case in which the offset voltage is applied to all outputs of the output unit 230, it may be appreciated that a predetermined voltage is applied even in a standby state section Pin before an actual waveform is output. Since the voltage applied in the standby state section Pin may be noise to the piezoelectric element, the correcting unit 240 may correct the voltage applied in the standby state section Pin.

FIG. 10 illustrates an example of differential signals corrected by the correcting unit.

The correcting unit 240 may correct the offset voltage for at least some sections of the asymmetrical driving signal.

In the example illustrated in FIG. 10, it may be appreciated from the differential signals corrected by the correcting unit 240 that the predetermined voltage applied in the standby state section Pin is corrected. Therefore, the correcting unit 240 may remove noise which may be generated from the asymmetrical driving signal.

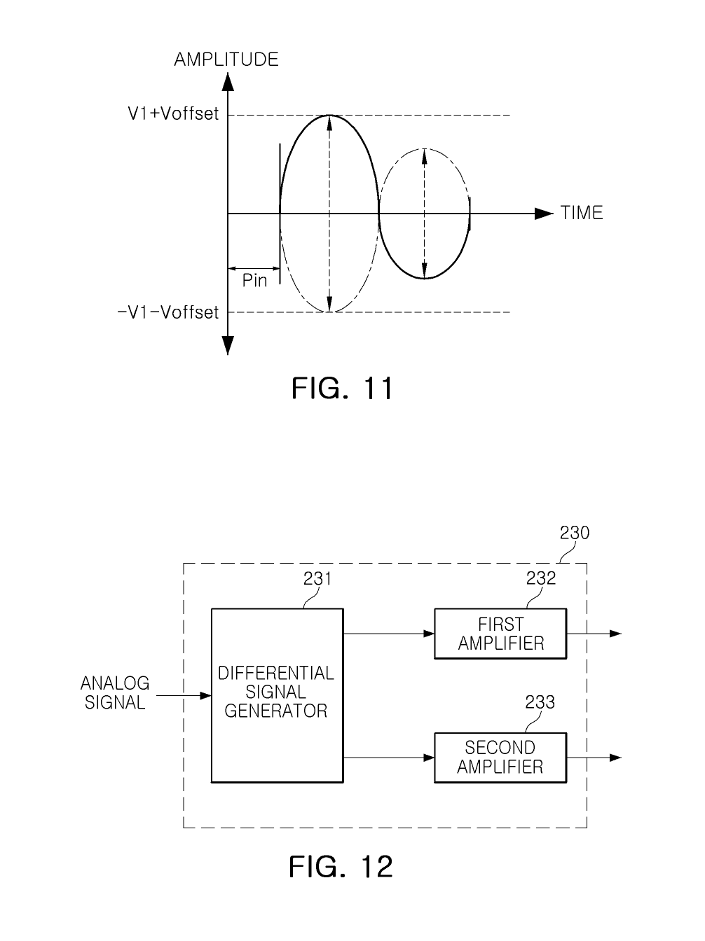

FIG. 11 is a graph illustrating the differential signals of FIG. 10 as one driving signal.

FIG. 11 may be derived by subtracting the other differential signal from one differential signal of FIG. 10. As illustrated in FIG. 11, it may be appreciated that the driving signal applied to the multilayer piezoelectric element is an asymmetrical signal having positive amplitude larger than negative amplitude.

As described above with reference to FIGS. 8 through 11, the signal provided by the piezoelectric driving apparatus 200 may be the asymmetrical signal. Thereby, a high output may be obtained while the negative threshold value of the multilayer piezoelectric element 100 is satisfied.

Again, an exemplary piezoelectric driving apparatus 200 will be described in more detail with reference to FIGS. 6 and 7.

The piezoelectric driving apparatus 200 includes the waveform synthesizing unit 210, the converting unit 220, the output unit 230, and the correcting unit 240.

According to an exemplary embodiment in the present disclosure, the components of the piezoelectric driving apparatus 200 may be implemented in discrete circuits, integrated circuits, or elements, or incorporated so as to be implemented in a single circuit or integrated circuit.

The waveform synthesizing unit 210 may output a predetermined digital value (hereinafter, referred to as ‘digital code’) for generating the driving signal. The digital code may be converted into the analog signal by the converting unit 220, and the analog signal may be converted into the differential signals by the output unit 230 so as to be applied to the multilayer piezoelectric element 100.

According to an exemplary embodiment in the present disclosure, the waveform synthesizing unit 210 may output the digital code based on an external input. The external input, which is a signal input from the outside of the piezoelectric driving apparatus, may be provided from, for example, a main central processing unit (CPU), a control integrated circuit (IC), a main control unit (MCU), or the like, of a mobile device, or the like including the piezoelectric driving apparatus.

According to an exemplary embodiment, the waveform synthesizing unit 210 may output the digital code using a lookup table. For example, the waveform synthesizing unit 210 may select some of the look up table in which a plurality of digital values are stored and output the digital code.

According to another exemplary embodiment, the waveform synthesizing unit 210 may output the digital code using a function that outputs a predetermined digital value depending on the external input. For example, the function may output the digital code by applying a preset equation to the external input.

According to an exemplary embodiment, the waveform synthesizing unit 210 may generate the asymmetrical driving signal by applying an offset value to the output digital value. That is, the waveform synthesizing unit 210 may generate the asymmetrical driving signal by adding and outputting a predetermined offset value to a selected digital value. In a case of an exemplary embodiment described above, the output unit 230 may not apply the offset voltage. In addition, in a case of an exemplary embodiment described above, the correcting unit 240 may be connected to the waveform synthesizing unit 210 as illustrated in FIG. 7 and control the waveform synthesizing unit 210 so as not to apply the offset value to at least some sections of the asymmetrical driving signal.

The converting unit 220 may output an analog signal corresponding to the digital code. According to an exemplary embodiment, the converting unit 220 may be a digital-to-analog converter.

The output unit 230 may receive the analog signal and output a pair of differential signals using the received analog signal.

According to an exemplary embodiment, the output unit 230 generates the asymmetrical driving signal by applying a predetermined offset voltage to the analog signal. As described above with reference to FIG. 9, it may be appreciated that the bold solid line illustrates a case in which the positive offset voltage value Voffset is applied and an alternating long and short dashed line illustrates a case in which the negative offset voltage value is applied. As such, the output unit 230 may generate an asymmetrical differential signal by applying the predetermined offset voltage value to the analog signal.

According to an exemplary embodiment, the output unit 230 may add the offset voltage to an analog voltage waveform output from the converting unit 220.

According to an exemplary embodiment, the output unit 230 generates a pair of differential signals using the analog value output from the converting unit 220 and may respectively apply the pair of differential signals to both terminals of the multilayer piezoelectric element.

According to an exemplary embodiment, the output unit 230 applies a positive offset voltage to the differential signal which is input to the positive input terminal of the multilayer piezoelectric element 100 and applies a negative offset voltage to the differential signal which is input to the negative input terminal of the multilayer piezoelectric element 100.

According to an exemplary embodiment, the output unit 230 may generate an output waveform using the input analog value and shift the same to output the shifted waveform. As described above with reference to FIG. 9, it may be appreciated that the waveform denoted by the bold solid line is shifted in a positive direction by the offset voltage value Voffset and the waveform denoted by the alternating long and short dash line is shifted in a negative direction by the offset voltage value.

The correcting unit 240 may correct the offset voltage for at least some temporal, polarity, or magnitude-based sections of the asymmetrical driving signal.

According to an exemplary embodiment, the correcting unit 240 may allow the offset voltage not to be applied to the asymmetrical driving signal for the standby state section of the asymmetrical driving signal.

Hereinafter, various exemplary embodiments of the piezoelectric driving apparatus 200 will be described with reference to FIGS. 12 through 16.

FIG. 12 is a configuration diagram illustrating an example of an output unit of the piezoelectric driving apparatus.

Referring to FIG. 12, the output unit 230 may include a differential signal generator 231 and first and second amplifiers 232 and 233.

The differential signal generator 231 may receive the analog signal and may output a pair of differential signals. According to an exemplary embodiment, the differential signal generator 231 may generate the differential signals using the received analog signal and a signal obtained by delaying the analog signal to an opposite phase.

The first and second amplifiers 232 and 233 may form the received differential signals to be asymmetrical by applying an offset voltage to the differential signals, respectively. The first and second amplifiers 232 and 233 may amplify and output the received differential signals.

Since the first and second amplifiers 232 and 233 apply the offset voltage, the first and second amplifiers 232 and 233 may be substituted with other components performing the function described above. Depending on exemplary embodiments, a level shifter, or the like may be used instead of the first and second amplifiers 232 and 233.

According to an exemplary embodiment, the first amplifier 232 and the second amplifier 233 may respectively apply the offset voltage values having magnitude corresponding to each other or having signs opposite to each other. For example, the first amplifier 232 may apply an offset voltage having a positive value to the received differential signal and the second amplifier 233 may apply an offset voltage having a negative value to the received differential signal.

According to an exemplary embodiment, the first amplifier 232 may shift the waveform of a first differential signal in a positive voltage direction by applying the positive offset voltage to the first differential signal and the second amplifier 233 may shift the waveform of a second differential signal in a negative voltage direction by applying the negative offset voltage to the second differential signal.

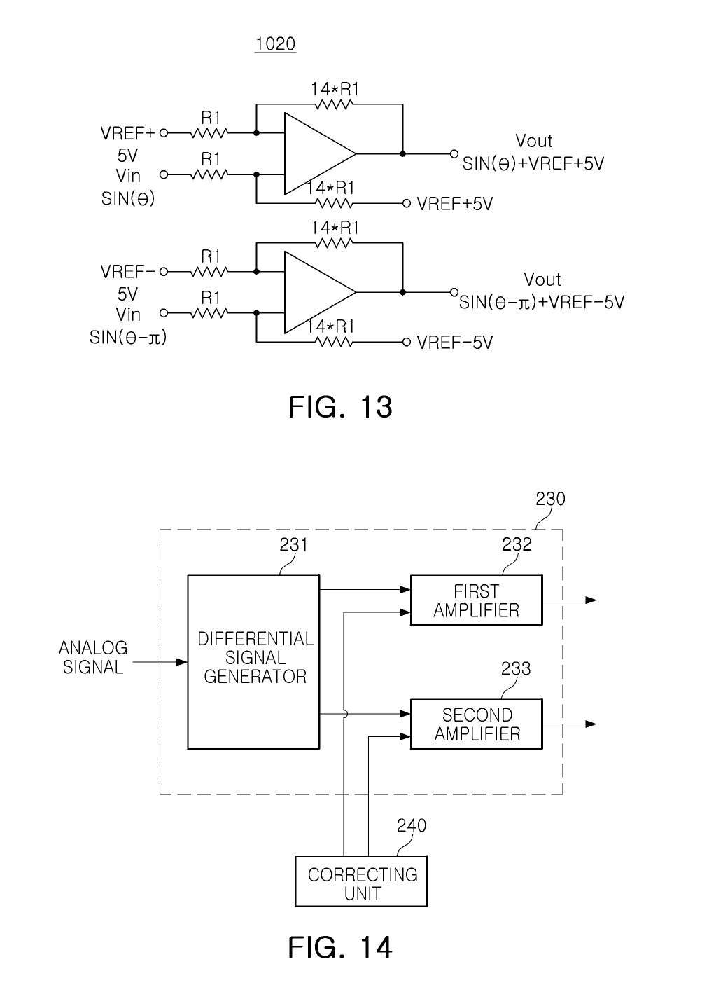

FIG. 13 is a circuit diagram illustrating an example of the amplifier of FIG. 12. FIG. 13 relates to an example in which a gain ratio of each signal may be set to about 14 and the offset voltage of about 5V may be each applied.

As illustrated in FIG. 13, it may be appreciated that the offset voltage of about +5V or about −5V is applied to a reference terminal of the amplifier. That is, by applying the offset voltage to the reference terminal, a reference value of the differential signal may be increased as much as the offset voltage. Therefore, an output of the amplifier may be shifted in the positive or negative direction as illustrated in FIG. 9.

FIG. 14 is a configuration diagram illustrating an example of a correcting unit which may be applied to the example of FIG. 12.

Referring to FIG. 14, the correcting unit 240 may perform a correction by controlling the first and second amplifiers 232 and 233 so as to selectively apply the offset voltage or so as not to apply the offset voltage.

For example, the correcting unit 240 may determine whether or not the first and second amplifiers are in the standby state section, and may control the first and second amplifiers so as not to provide the offset voltage in the standby state section.

According to an exemplary embodiment, the correcting unit 240 may determine whether the standby state section is or is not presently active by using at least one of the digital value output from the waveform synthesizing unit 210 or the analog signal output from the converting unit 220.

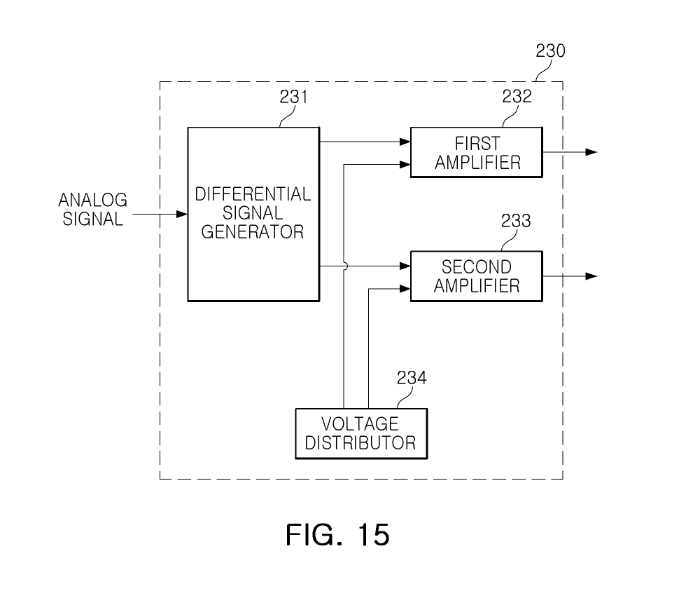

FIG. 15 is a configuration diagram illustrating another example of the output unit of the piezoelectric driving apparatus.

Referring to FIG. 15, the output unit 230 may include the differential signal generator 231, the first and second amplifiers 232 and 233, and a voltage distributor 234.

The first and second amplifiers 232 and 233 may apply the offset voltage value to the differential signals using a reference voltage.

The voltage distributor 234 may provide the offset voltage to the first and second amplifiers 232 and 233. For example, the offset voltage value may be a preset voltage value and the voltage distributor 234 may provide the offset voltage to reference terminals of the first and second amplifiers 232 and 233.

According to an exemplary embodiment, the voltage distributor 234 may be connected to the reference terminals of the first and second amplifiers 232 and 233 so as to provide the offset voltage to the first and second amplifiers 232 and 233, respectively.

According to an exemplary embodiment, the voltage distributor 234 may adjust a magnitude of the offset voltage. For example, the voltage distributor 234 may include a voltage adjusting circuit and a distributing circuit, and may adjust the magnitude of the output offset voltage by adjusting the distributing circuit.

According to an exemplary embodiment, the voltage distributor 234 may provide or block the offset voltage to the first and second amplifiers depending on a mode input signal which may be input from an external location such as the correcting unit 240, a controller, or the like.

For example, the correcting unit 240 may control the voltage distributor 234 so as to selectively provide or block the offset voltage to the first and second amplifiers. That is, the voltage distributor 234 may determine the offset voltage value to zero by the control of the correcting unit 240.

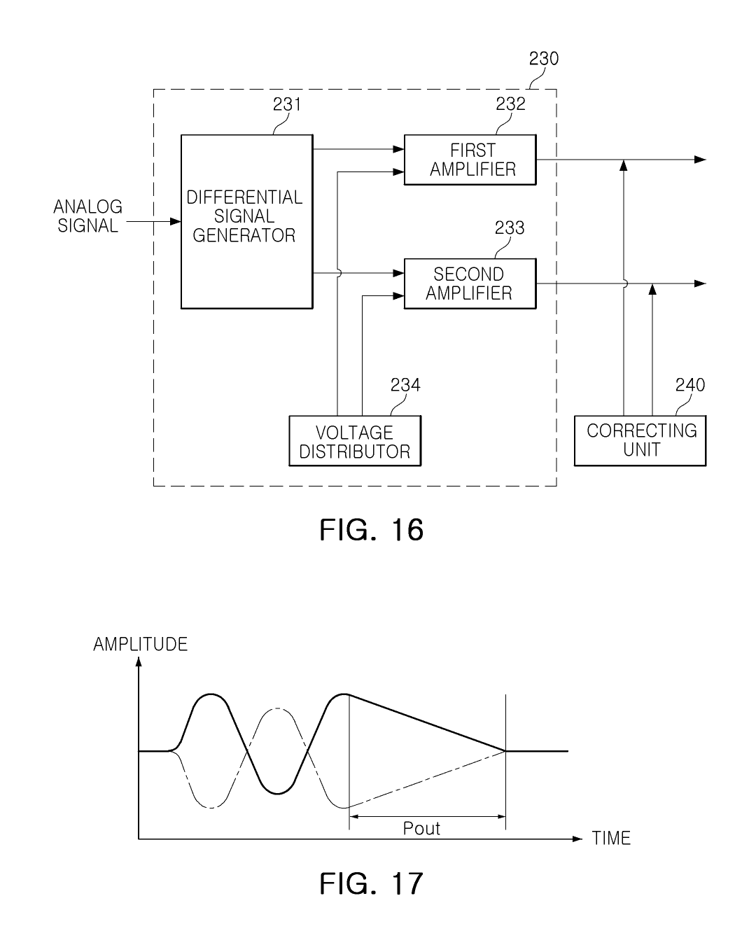

FIG. 16 is a configuration diagram illustrating an example of a correcting unit which may be applied to the example of FIG. 15.

Referring to FIG. 16, the correcting unit 240 may perform the correction by compensating for the outputs of the first and second amplifiers 232 and 233.

According to an exemplary embodiment, the correcting unit 240 may add or subtract the offset voltage from the outputs of the first and second amplifiers 232 and 233 in the standby state section.

According to an exemplary embodiment, in the case in which the asymmetrical driving signal corresponds to the standby state section, the correcting unit 240 may further apply the negative offset voltage to the differential signal input to the positive input terminal and may further apply the positive offset voltage to the differential signal input to the negative input terminal.

According to an exemplary embodiment, the correcting unit 240 may correct an output waveform so as to have a predetermined gradient in the case in which the generation of the driving signal ends. FIG. 17 is a graph illustrating an exemplary operation of the correction unit.

Referring to FIG. 17, it may be appreciated that an end section Pout of the driving signal has constant linearity. This is to provide a more stable driving, as compared to a case in which a voltage value is sharply set to 0 after the generation of the signal ends.

According to an exemplary embodiment, the correcting unit 240 may provide a plurality of digital values to be sequentially output by repeatedly subtracting a predetermined value from a digital value corresponding to a final value of the driving signal in the case in which the generation of the driving signal ends.

Hereinabove, various exemplary embodiments of the piezoelectric driving apparatus applying the asymmetrical waveform have been described with reference to FIGS. 6 through 17.

Although the description described above is made based on a case in which the offset voltage value is applied to both the pair of differential signals, the asymmetrical driving may be performed by applying the offset voltage value to only any one of the pair of differential signals, depending on exemplary embodiments.

In addition, although the description described above is made based on an exemplary embodiment in which the differential signals are each generated and the offset voltage value is then applied to the differential signals, the differential signals may also be generated after applying the offset voltage value to the analog signal, depending on exemplary embodiments.

The piezoelectric driving apparatus described above may stably generate the asymmetrical signal using only a single voltage. Therefore, the piezoelectric driving apparatus may stably generate the asymmetrical driving signal even in an environment in which a source voltage is limited such as a mobile terminal such as a cellular phone, a tablet PC, or the like, navigation for vehicle, or the like, and may provide a higher output using the asymmetrical driving signal.

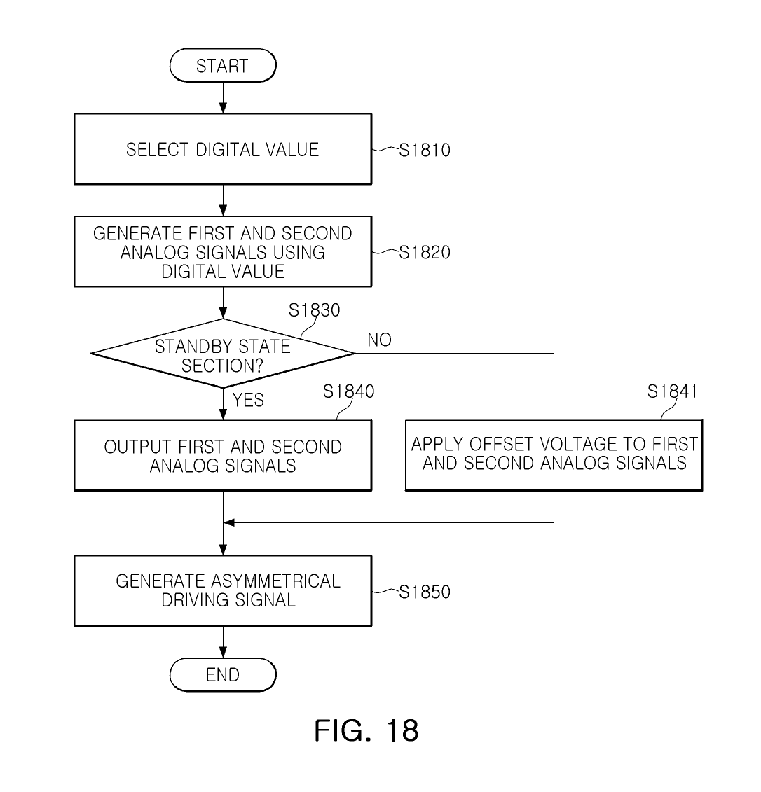

FIG. 18 is a flowchart illustrating an example of a piezoelectric driving method. Since a piezoelectric driving method to be described below may be performed by the piezoelectric driving apparatus described above with reference to FIGS. 1 through 17, an overlapped description for contents that are the same as or correspond to the above-mentioned contents will be omitted.

Referring to FIG. 18, the piezoelectric driving apparatus selects a digital value (S1810).

The piezoelectric driving apparatus generates first and second analog signals using the digital value (S1820).

The piezoelectric driving apparatus determines whether a standby state section is or not active (S1830) and generates an asymmetrical driving signal (S1850) by applying offset voltages having opposite polarities to the first and second analog signals (S1840) when the first and second analog signals are not in the standby state section (No determined in S1830).

Alternatively, the piezoelectric driving apparatus may generate the asymmetrical driving signal (S1850) by outputting the first and second analog signals (S1840) in the standby state section (Yes determined in S1830).

The apparatuses, units, modules, devices, and other components illustrated in FIGS. 1, 6-7, 12-16 that perform the operations described herein with respect to FIGS. 3-4, 8, and 18 are implemented by hardware components. Examples of hardware components include controllers, sensors, generators, drivers, and any other electronic components known to one of ordinary skill in the art. In one example, the hardware components are implemented by one or more processors or computers. A processor or computer is implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices known to one of ordinary skill in the art that is capable of responding to and executing instructions in a defined manner to achieve a desired result. In one example, a processor or computer includes, or is connected to, one or more memories storing instructions or software that are executed by the processor or computer. Hardware components implemented by a processor or computer execute instructions or software, such as an operating system (OS) and one or more software applications that run on the OS, to perform the operations described herein with respect to FIGS. 3-4, 8, and 18. The hardware components also access, manipulate, process, create, and store data in response to execution of the instructions or software. For simplicity, the singular term “processor” or “computer” may be used in the description of the examples described herein, but in other examples multiple processors or computers are used, or a processor or computer includes multiple processing elements, or multiple types of processing elements, or both. In one example, a hardware component includes multiple processors, and in another example, a hardware component includes a processor and a controller. A hardware component has any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 3-4, 8, and 18 that perform the operations described herein are performed by a processor or a computer as described above executing instructions or software to perform the operations described herein.

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In another example, the instructions or software include higher-level code that is executed by the processor or computer using an interpreter. Programmers of ordinary skill in the art can readily write the instructions or software based on the block diagrams and the flow charts illustrated in the drawings and the corresponding descriptions in the specification, which disclose algorithms for performing the operations performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any device known to one of ordinary skill in the art that is capable of storing the instructions or software and any associated data, data files, and data structures in a non-transitory manner and providing the instructions or software and any associated data, data files, and data structures to a processor or computer so that the processor or computer can execute the instructions. In one example, the instructions or software and any associated data, data files, and data structures are distributed over network-coupled computer systems so that the instructions and software and any associated data, data files, and data structures are stored, accessed, and executed in a distributed fashion by the processor or computer.

As set forth above, according to exemplary embodiments of the present disclosure, characteristics of the multilayer piezoelectric element may be protected and the high output may be stably provided at the same time.

While exemplary embodiments have been shown and described above, it will be apparent to those skilled in the art that modifications and variations could be made without departing from the scope of the present invention as defined by the appended claims.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A piezoelectric driving apparatus comprising:
a waveform generator configured to output an alternating current (AC) signal;
an output unit configured to apply an offset voltage to the AC signal to generate and output an asymmetrical driving signal; and
a correcting unit configured to correct the offset voltage in at least one section of the asymmetrical driving signal of a piezoelectric element.

2. The piezoelectric driving apparatus of claim 1, wherein the waveform generator includes:
a waveform synthesizer configured to output a digital value; and
a digital-to-analog converter configured to output an analog value corresponding to the digital value.

3. The piezoelectric driving apparatus of claim 1, wherein the correcting unit is configured to selectively prevent the offset voltage from being applied to the asymmetrical driving signal in a standby state section of the asymmetrical driving signal.

4. The piezoelectric driving apparatus of claim 2, wherein the output unit is configured to generate a pair of differential signals using the analog value and apply the pair of differential signals to both terminals of the piezoelectric element, respectively.

5. The piezoelectric driving apparatus of claim 4, wherein the output unit is configured to apply a positive offset voltage to one of the differential signals input to a positive input terminal of the piezoelectric element and apply a negative offset voltage to the other of the differential signals input to a negative input terminal of the piezoelectric element.

6. The piezoelectric driving apparatus of claim 5, wherein the correcting unit is further configured to apply the negative offset voltage to the differential signal input to the positive input terminal and apply the positive offset voltage to the differential signal input to the negative input terminal in the standby state section of the asymmetrical driving signal.

7. The piezoelectric driving apparatus of claim 2, wherein the output unit includes:
a differential signal generator configured to generate a pair of differential signals using the analog value; and
first and second amplifiers configured to apply the offset voltage to the pair of differential signals, respectively.

8. The piezoelectric driving apparatus of claim 7, wherein the correcting unit is configured to subtract the offset voltage from output values of the first and second amplifiers in a standby state section of the asymmetrical driving signal.

9. The piezoelectric driving apparatus of claim 7, wherein the correcting unit is configured to control the first and second amplifiers to block the offset voltage in a standby state section of the asymmetrical driving signal.

10. The piezoelectric driving apparatus of claim 7, wherein the output unit further includes a voltage distributor connected to reference terminals of the first and second amplifiers and is configured to provide the offset voltage to each of the first and second amplifiers.

11. The piezoelectric driving apparatus of claim 1, wherein the correcting unit is configured to sequentially output a plurality of digital values by repeatedly subtracting a predetermined value from a final digital value of the driving signal when the generating of the driving signal ends.

12. A piezoelectric driving apparatus comprising:
a waveform synthesizer configured to output a digital value;
a digital-to-analog converter configured to output an analog value corresponding to the digital value;
an output unit configured to generate an output waveform using the analog value and shift the same to output a shifted waveform; and
a correcting unit configured to control the output unit to block a shift operation in at least one section of the output waveform.

13. The piezoelectric driving apparatus of claim 12, wherein the output unit includes:
a differential signal generator configured to generate a pair of differential signals using the analog value; and
first and second amplifiers configured to apply an offset voltage to the pair of differential signals, respectively.

14. The piezoelectric driving apparatus of claim 13, wherein the first amplifier is configured to apply a positive offset voltage to a first differential signal of the pair of differential signals to shift a waveform of the first differential signal in a positive voltage direction, and
the second amplifier is configured to apply a negative offset voltage to a second differential signal of the pair of differential signals to shift a waveform of the second differential signal in a negative voltage direction.

15. The piezoelectric driving apparatus of claim 13, wherein the correcting unit is configured to control the first and second amplifiers to selectively block the shift operation in a standby state section of the output waveform.

16. The piezoelectric driving apparatus of claim 12, wherein the correcting unit is configured to correct the output waveform to have a predetermined gradient when the generating of the output waveform ends.

17. A piezoelectric driving apparatus for driving a piezoelectric element in which a plurality of piezoelectric layers are stacked, the piezoelectric driving apparatus comprising:
an output unit configured to provide a first differential signal to which a positive offset voltage has been applied to a positive input terminal of the piezoelectric element, and provide a second differential signal to which a negative offset voltage has been applied to a negative input terminal of the piezoelectric element; and
a correcting unit configured to control the output unit to block the positive offset voltage and/or the negative offset voltage in at least one section of the first and second differential signals.

18. The piezoelectric driving apparatus of claim 17, wherein the piezoelectric driving apparatus further includes:
a waveform synthesizer configured to output a digital value;
a digital-to-analog converter configured to output an analog value corresponding to the digital value; and
an output unit configured to apply an offset voltage to the analog value to generate an asymmetrical driving signal.

19. The piezoelectric driving apparatus of claim 18, wherein the output unit is configured to apply the positive offset voltage to the first differential signal, and apply the negative offset voltage to the second differential signal.

20. The piezoelectric driving apparatus of claim 18, wherein the correcting unit is further configured to apply the negative offset voltage to the first differential signal, and apply the positive offset voltage to the second differential signal in a standby state section of the asymmetrical driving signal.

21. The piezoelectric driving apparatus of claim 18, wherein the correcting unit is further configured to control the output unit to selectively block the positive and negative offset voltages in a standby state section of the asymmetrical driving signal.

22. A piezoelectric driving method comprising:
selecting a digital value;
generating first and second analog signals using the digital value;
applying offset voltages having opposite polarities and magnitudes to the first and second analog signals to generate an asymmetrical driving signal when the first and second analog signals are not in a standby state section; and,
driving a multi-layer piezoelectric element according to the asymmetrical driving signal.

23. The piezoelectric driving method of claim 22, further comprising outputting the first and second analog signals in the standby state section.

24. A non-transitory computer-readable medium storing instructions for causing a controller to perform the method of claim 22.

25. A multi-layer piezoelectric actuator comprising:
a plurality of piezoelectric layers arranged in stacked relation, each piezoelectric layer having a predetermined thickness;
a plurality of alternatingly arranged first and second electrodes disposed within the stacked piezoelectric layers;
a piezoelectric driver coupled to the first and second electrodes, the piezoelectric driver configured to adaptively adjust an asymmetric driving signal according to at least the predetermined thickness and/or number of piezoelectric layers, the asymmetric driving signal having an absolute value of a magnitude of a positive polarity greater than an absolute value of a magnitude of a negative polarity.

26. The multi-layer piezoelectric actuator of claim 25, wherein the plurality of piezoelectric layers includes about 8 to about 24 layers and each layer is about 15 μm to about 100 μm thick.
